(19) United States
(12) Patent Application Publication
(10) Pub. No.: US 2016/0041318 A1
(43) Pub. Date: Feb. 11, 2016

(54) Broadband Absorptive Neutral Density Optical Filter

(71) Applicants: Marc Currie, Washington, DC (US); David Kurt Gaskill, Alexandria, VA (US)

(72) Inventors: Marc Currie, Washington, DC (US); David Kurt Gaskill, Alexandria, VA (US)

(73) Assignee: The Government of the United States of America, as represented by the Secretary of the Navy, Washington, DC (US)

(21) Appl. No.: 14/886,409

(22) Filed: Oct. 19, 2015

Related U.S. Application Data
(63) Continuation of application No. 13/558,429, filed on Jul. 26, 2012.
(60) Provisional application No. 61/512,022, filed on Jul. 27, 2011.

(51) Int. Cl. G02B 5/20; C23C 16/44; C23C 16/26

(52) U.S. Cl. CPC G02B 5/205; G02B 5/208; G02B 5/204; C23C 16/26; C23C 16/44

(57) ABSTRACT

A method for fabricating an absorptive neutral density optical filter comprising one or more graphene layers disposed on an optical substrate. The optical substrate can be a solid material (e.g. glasses or crystals such as silicon carbide, sapphire, germanium, or potassium bromide), or a polymer, or even a wire mesh. The graphene can be grown on the optical substrate or can be growth on a growth substrate and then transferred to the optical substrate.

### CROSS-REFERENCE

This application is a continuation of, and claims the benefit of priority under 35 U.S.C. §120 based on, U.S. patent application Ser. No. 13/558,429 filed on Jul. 26, 2012, which in turn is a Nonprovisional of, and claims the benefit of priority under 35 U.S.C. §119 based on, U.S. Provisional Patent Application No. 61/512,022 filed on Jul. 27, 2011, both of which are hereby incorporated by reference into the present application in their entirety.

### TECHNICAL FIELD

The present invention relates to optical filters, specifically to optical filters configured to filter electromagnetic radiation by uniform absorption over a broad spectral bandwidth.

### BACKGROUND

A variety of optical applications use absorptive optical filters to control the intensity of light. An absorptive filter attenuates the incoming light by a specified value, often described by an optical density value. If attenuation value is valid over an optical spectral range, the filter is said to have a neutral optical density, and is referred to as an “absorptive neutral density filter.” See M. Bass, J. M. Enoch, and V. Lakshminarayanan, Handbook of Optics, Volume III—Vision and Vision Optics (3^{rd} Edition), McGraw-Hill (2010), pp. 5-14.

One issue with many absorptive neutral density filters is their inability to maintain a constant attenuation value over a broad optical wavelength range. Several are acceptable in the visible spectral region (450-700 nm), but their optical transmission characteristics deviate outside this region. See P. W. Baumeister, Optical Coating Technology, SPIE (2004) pp. 8-35; see also Knovel Optical Filter Glass Database (2011).

In addition, absorptive neutral density filters are usually created on (or within) a single substrate. This limits the applicability and adds elements to optical systems.

Finally, the performance of currently available absorptive neutral density filters degrades with increasing optical power due to the increased heating from absorption.

Thus, there is a desire to produce better absorptive neutral density filters that can maintain a constant attenuation value over a broad optical wavelength range and do not degrade with increasing optical power.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a broadband absorptive neutral density optical filter comprising one or more graphene layers disposed on an optical substrate. An optical filter in accordance with the present invention can filter light by uniform absorption over a broad optical spectral bandwidth. For ease of reference, the terms “optical” and “light” are used herein to refer to electromagnetic radiation from the visible light range to the THz range, i.e., having wavelengths from about 400 nanometers to about 1 millimeter. An optical filter in accordance with the present invention differs significantly from currently available absorptive neutral density filters by its ability to maintain a uniform level of absorption throughout this entire wavelength region.

The optical filter in accordance with the present invention can be applied to a wide range of optical substrates.

The absorptance or transmittance of an optical filter in accordance with the present invention will depend on the optical characteristics of the substrate used and the number of graphene layers present. For any given substrate, the absorptance/transmittance of a broadband absorptive neutral density optical filter in accordance with the present invention can be easily tuned by varying the number of graphene layers disposed thereon, thus allowing its use in a wide variety of optical assemblies and components.

In addition, the optical filter in accordance with the present invention rapidly conducts the heat away from the absorbing region, and therefore can be used in applications having higher optical power than can be used with conventional absorptive neutral density filters.

### BRIEF DESCRIPTION OF THE DRAWINGS

FIG. 1 is a plot illustrating the difficulty in producing a constant absorption in the region from the 700-1400 nm region.

FIGS. 2A and 2B are images illustrating the attenuation in transmittance through different thicknesses of graphene layers, where FIG. 2A is an image of the graphene-on-SiC sample whose attenuation is illustrated in FIG. 2B.

FIG. 3 is an image illustrating aspects of light transmittance through a broadband absorptive neutral density optical filter in accordance with the present invention.

FIGS. 4A and 4B are plots illustrating uniformity of light transmittance by a broadband absorptive neutral density optical filter in accordance with the present invention over a wide range of wavelengths.

FIG. 5 is a block diagram illustrating aspects of formation of a broadband absorptive neutral density optical filter in accordance with an exemplary embodiment of the present invention.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

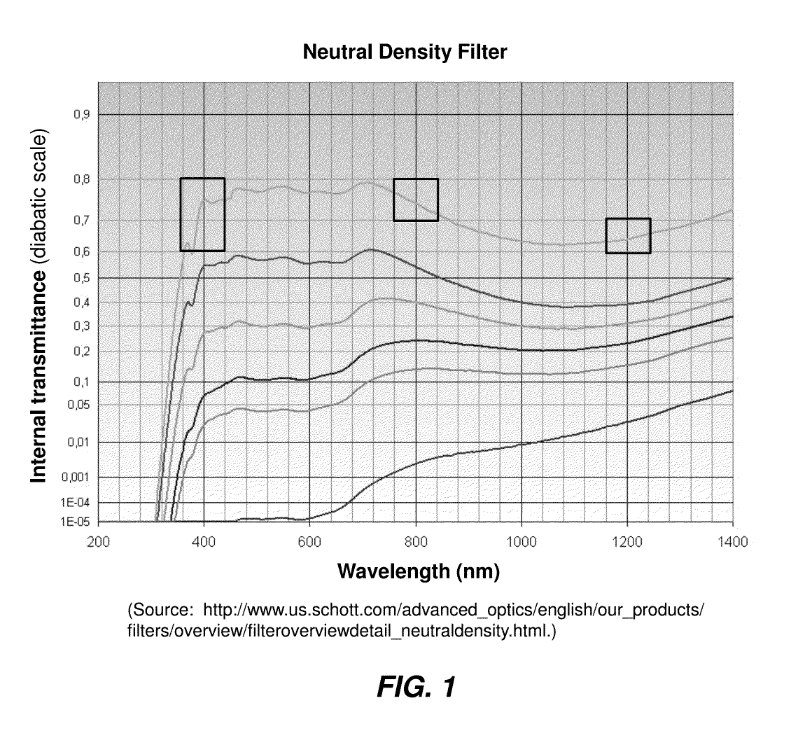

As described above, a key issue with conventional absorptive neutral density optical filters is their inability to maintain a constant attenuation value over a broad optical wavelength range. The plots in FIG. 1 illustrate this problem. FIG. 1 plots the transmittance of various conventional doped glass filters from SCHOTT North America, Inc., with each plot showing the transmittance of a particular filter over a wavelength range of 700 to 1400 nm. See http://www.us.schott.com/advanced_optics/english/our_products/filtersoverview/filteroverviewdetail_neutral density.html. As can be seen from the plots in FIG. 1, these conventional glass filters exhibit highly non-uniform internal transmittance (absorption) over the 700-1400 nm wavelength range, with each of them exhibiting a significantly different transmittance at 400 nm than at 750 nm, 1000 nm, or 1400 nm.

More significantly, such filters exhibit non-uniform transmittance over even a narrow spectral range. For example, as can easily be seen from the plots in FIG. 1, conventional doped glass filters exhibit very different transmittance over the 360-420 nm range, over the 760-820 nm range, or over the 1160-1220 nm range.

Such non-uniform transmittance can create problems with time-frequency domain optical signals such as femtosecond optical pulses or short THz pulses. The temporal and spectral attributes of such pulses are coupled such that changes in the pulse's spectrum will change its temporal profile. Thus, if the pulse is not attenuated uniformly over its entire spectral width as it is transmitted through a filter, its temporal profile will be distorted with the change in its spectral profile. This is particularly a problem with THz pulses as well as femtosecond optical pulses due to their broad spectral bandwidth, and so limits the usefulness of conventional filters for pulsed THz and optical applications.

The present invention solves this problem and provides absorptive neutral density optical filters that have a largely uniform response across a wide optical spectrum.

It will be noted here that for ease of reference, the terms “optical” and “light” are used herein to refer to electromagnetic radiation from the visible light range to the THz range, i.e., having wavelengths from about 400 nanometers to about 1 millimeter. It will also be noted that the terms optical “transmission” and “transmittance” and optical “absorption” and “absorptance” are used herein to refer to a material's ability to transmit or absorb radiation at a particular wavelength, more specifically transmission is the ratio of transmitted light to incident light and similarly absorptance is the ratio of absorbed light to that of the incident light.

It has been demonstrated that a single layer of graphene absorbs roughly 2.3% of the incident light. See R. R. Nair, P. Blake, A. N. Grigorenko, K. S. Novoselov, T. J. Booth, T. Stauber, N. M. R. Peres, and A. K. Geim, “Fine Structure Constant Defines Visual Transparency of Graphene,” SCIENCE, Vol. 320, p. 1308 (2008), which is hereby incorporated by reference into the present disclosure. This absorption is essentially uniform over a wide spectral range of about 400 nm to about 1 millimeter as it is defined theoretically through its relation with the fine structure constant of the material. Small variations are believed to be the result of impurities and resonances in graphene and are currently the subject of additional research. See Z. Li, C. H. Lui, E. Cappelluti, L. Benfatto, K. F. Mak, G. L. Carr, J. Shan, and T. F. Heintz, “Structure-Dependent Fano Resonances in the Infrared Spectra of Phonons in Few-Layer Graphene,” Phys. Rev. Lett. 108, 156801 (2012).

The present invention utilizes these properties of graphene to provide a broadband absorptive neutral density optical filter that can absorb light uniformly across all wavelengths of the optical spectrum.

A broadband absorptive neutral density optical filter in accordance with the present invention comprises one or more layers of graphene disposed on an optical substrate.

The absorption of such a filter increases as the number of layers of graphene increases. For example, if the absorption of a single layer of graphene is 0.023 (2.3%), then the transmission of one layer of graphene is (1−0.023). If after one layer the transmitted fraction of the light incident on the graphene is (1−0.023), a subsequent layer of graphene will absorb another 2.3% while transmitting a (1−0.023)*(1−0.023) fraction of the light incident on the two layer graphene stack. If three layers of graphene are used, the fraction of transmitted light will be (1−0.023)*(1−0.023)*(1−0.023), and so on, such that the transmission of such a filter is (1−0.023)ⁿ.

Thus, in accordance with the present invention, the absorption/transmission provided by a filter on a given optical substrate can be easily tuned by varying the number of graphene layers used. In addition, in some cases, the material properties of one or more layers of the graphene used can be altered to increase or decrease the per layer absorption provided.

In addition, the total absorption/transmission provided by an optical filter in accordance with the present invention depends not only on the number and characteristics of the graphene but also on the optical qualities of the substrate used.

For example, although the graphene portion of the filter is neutral, absorbing and transmitting uniformly across a wide spectral range, the material used for the substrate may not exhibit the same neutrality. In most cases it is desirable to choose a substrate that does not have significant optical absorption in the spectral range of interest. The substrate can vary by application and composition, and can include any suitable substrate, such as solid materials, polymers, or wire mesh, depending on the wavelength range of interest. For example, substrates for the near to far IR can include solids and crystals such as silicon carbide (SiC), sapphire, germanium (Ge), potassium bromide (KBr), etc., while for THz and millimeter wavelengths, a substrate consisting of a wire mesh may be more suitable.

The substrate will generally have an optical transmission T_{S} at each of its front and back surfaces, where T_{S} is the ratio of light that is transmitted through the filter at that surface to the light incident on that surface, such that the total optical transmission through the substrate (neglecting higher order effects of, e.g., internal reflection of the light within the substrate) is approximately T_{S}*T_{S}. Thus, in accordance with the present invention, an absorptive broadband neutral density optical filter having a desired optical transmission of T_{F} on an optical substrate having an optical transmission of T_{S} can be constructed using n layers of graphene, where T_{F}≈(T_{S}*T_{S})*(1−0.023)ⁿ. In a preferred embodiment, the substrate will have the optimal characteristics for the optical system, though in other embodiments the graphene layers can be integrated on an element of the optical system to remove any undesirable effects resulting from characteristics of the filter's optical substrate.

Because the absorption exhibited by graphene exhibits only a small variation over a wide spectral range, the number n of graphene layers required to filter any specific wavelength generally does not depend on the wavelength to be filtered. However, because of these small variations in graphene's absorption that may be present at different wavelengths, one skilled in the art would recognize that for a given substrate or a given wavelength range, in some embodiments fewer or more layers of graphene may be utilized to achieve the exact optical transmission/absorption value desired.

An absorptive neutral density optical filter in accordance with the present invention can be formed either by growing the graphene layers directly on a substrate such as SiC or by growing the graphene separately and then by transferring the graphene layers to a substrate, for example, as described in U.S. Pat. No. 8,753,468 Caldwell et al. entitled “Method for the Reduction of Graphene Film Thickness and the Removal and Transfer of Epitaxial Graphene Films from SiC Substrates” and in United States Patent Application Publication No. 2012/0244358 Lock et al., entitled “Dry Graphene Transfer from Metal Foils,” both of which share common ownership with the present application and are hereby incorporated into the present disclosure in their entirety. In some cases, the graphene layers can be grown and transferred to the substrate one at a time, while in other cases, multiple graphene layers can be grown, with the multiple layers being transferred to the substrate.

Such flexibility allows an absorptive neutral density optical filter in accordance with the present invention to be used with a variety of optical substrates as well as a wide range of optical devices. This can provide an advantage to reduce the number of elements within an optical system.

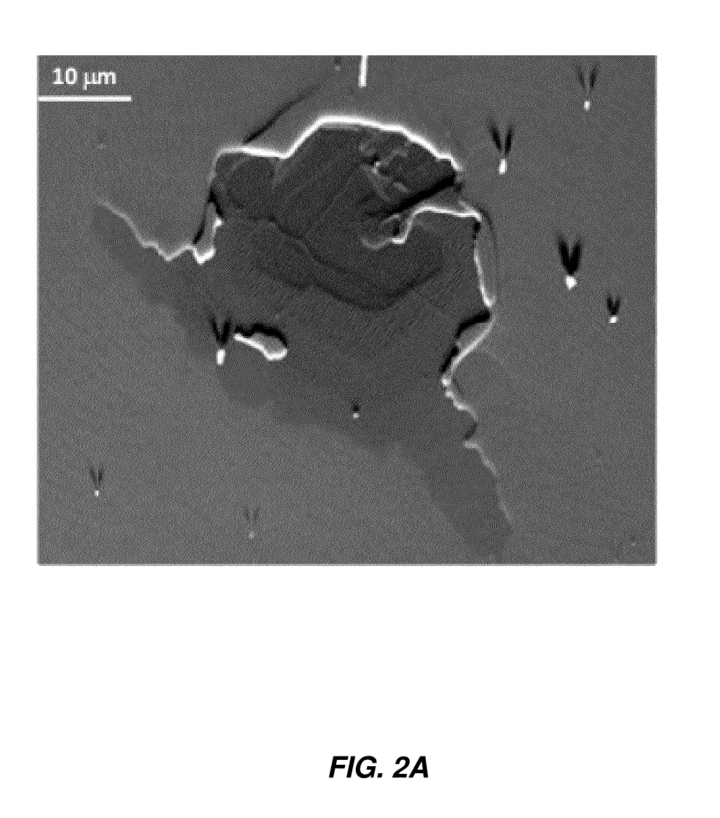

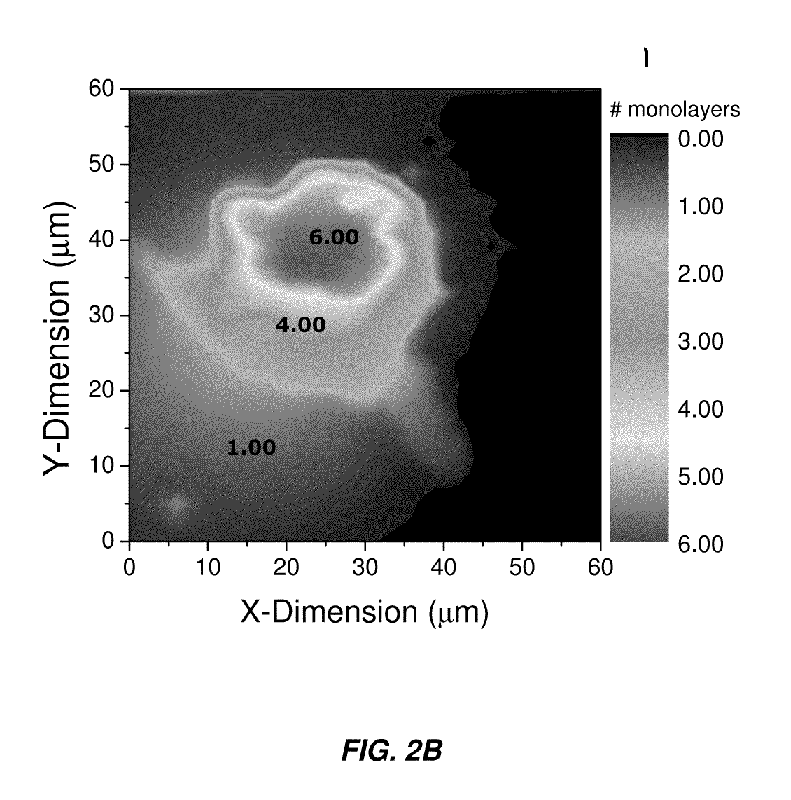

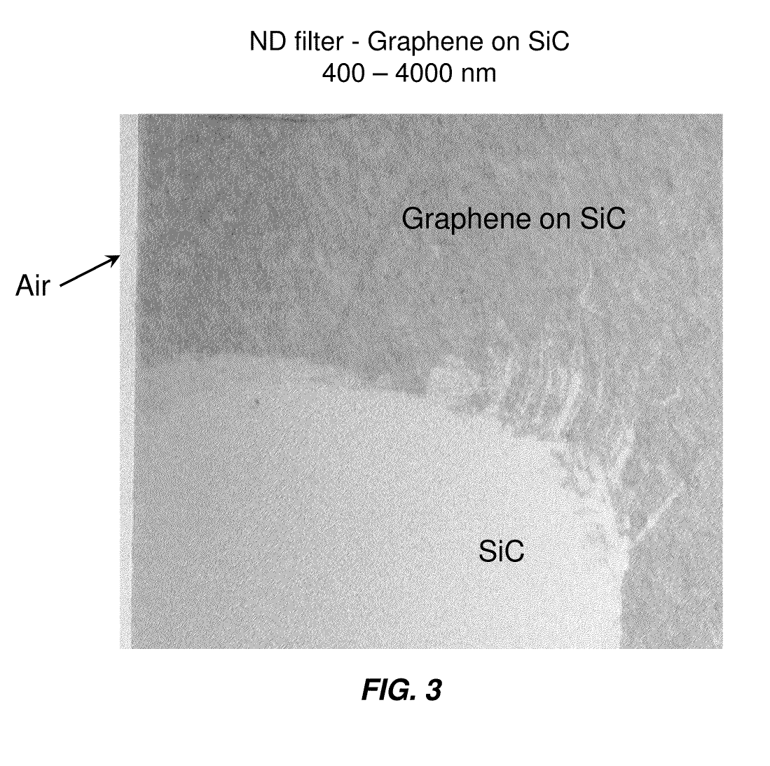

These aspects of the light absorption of an optical filter in accordance with the present invention are illustrated in FIGS. 2A and 2B and in FIG. 3.

FIG. 2A is a scanning electron micrograph image of a SiC substrate on which a number of graphene layers were grown. FIG. 2B is a plot showing the results of an analysis of the attenuation of the TO phonon signal acquired by Raman spectroscopy of the sample shown in FIG. 2A. The attenuation of the TO phonon signal was analyzed using the absorption values of graphene noted above, i.e., that the absorption exhibited by n layers of graphene is approximately 0.023ⁿ, to determine the number of layers present in the sample. After the analysis, a color value was assigned to the region containing one layer, another color for the region with two layers, etc. The resulting map of regions having different number of layers is shown in FIG. 2B. As can easily be seen from FIG. 2B, the attenuation of the light depends on the number of graphene layers present.

FIG. 3 is an image illustrating aspects of an exemplary embodiment of a broadband absorptive neutral density optical filter comprising graphene layers on an SiC substrate, where to illustrate the light transmittance properties, the graphene layers are applied to only a portion of the SiC substrate. Thus, FIG. 3 illustrates aspects of the light transmittance through such a filter, where the light is transmitted through the filter, traveling through the portion of the filter consisting of SiC without graphene, through the portion consisting of multi-layered graphene on SiC, and simply through the air. As can be seen from the photograph in FIG. 3, when light is shone on the graphene-covered SiC filter, the light transmittance through the graphene-on-SiC portion of the filter is significantly lower than the transmittance through the SiC portion, as shown by the dark/light contrasting regions in the photograph. The maximum light transmission (shown by the brightest region in the figure) is exhibited when the light does not travel through the filter, i.e., travels simply through the air, i.e. is not attenuated by either SiC or graphene.

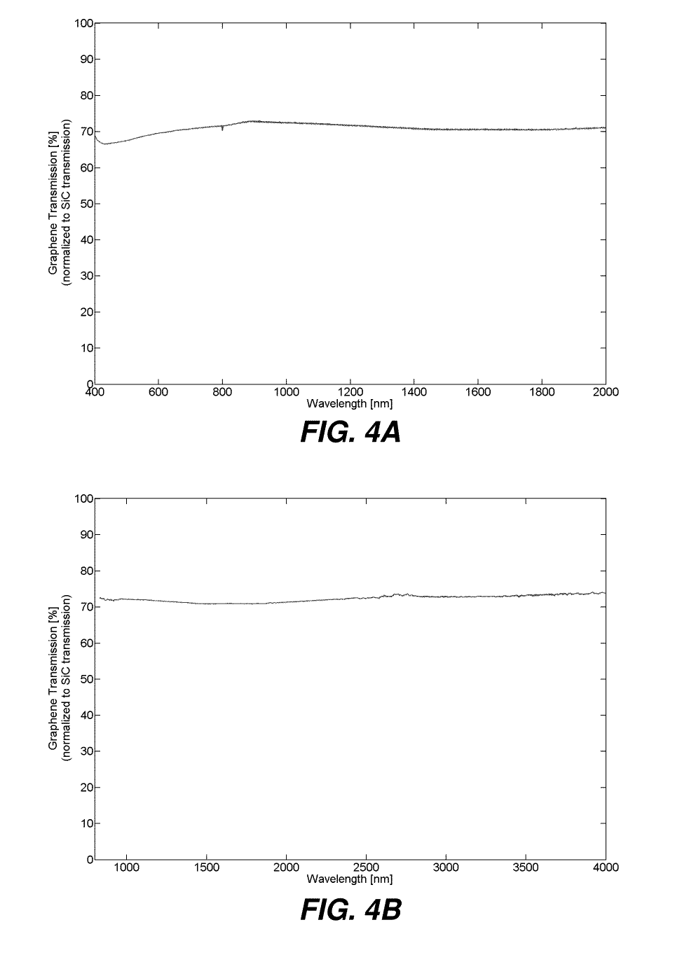

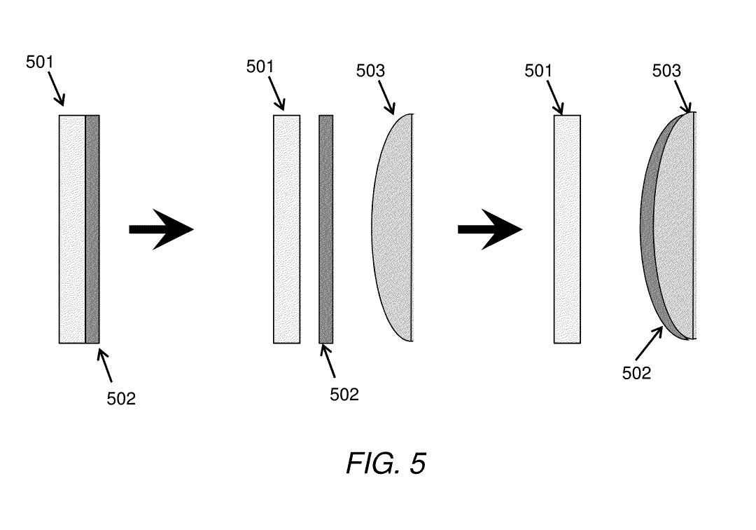

The plots in FIGS. 4A and 4B further illustrate aspects of the light attenuation achieved by a broadband absorptive neutral density optical filter in accordance with the present invention. As can be seen from the plots in FIGS. 4A and 4B, such a filter exhibits highly uniform attenuation over a wide wavelength range between 400 and 4000 nm, varying by only a small amount over that range. This is in stark contrast to the highly non-uniform attenuation of conventional filters as illustrated in FIG. 1 described above.

As noted above, since the attenuation achieved by use of graphene layers on a substrate is a function of the number of layers present, with an optical transmission reduction of about 2.3% per layer, a broadband absorptive neutral density optical filter can be easily tuned to achieve the desired optical transmission for any particular wavelength by varying the number of graphene layers used.

In addition, as noted above and as described below, because some substrate materials have differing optical properties, e.g., reflecting some of the incident light at certain angles, the number of graphene layers used can be adjusted to account for such properties of the substrate so that the desired transmission for the filter is achieved.

The present invention will now be further illustrated by reference to the following exemplary embodiments. It should be noted that the described embodiments are merely illustrative, and one skilled in the art will readily appreciate that such embodiments do not in any way limit the structure or other characteristics of a broadband absorptive neutral density optical filter in accordance with the present disclosure.

A first exemplary embodiment of a broadband absorptive neutral density optical filter in accordance with the present invention comprises one or more graphene layers epitaxially grown on SiC substrates. It should be noted that each surface of the SiC substrate will reflect approximately 20% of the incident light at near normal incidence and will transmit approximately 80%, such that the total percentage of the light transmitted by the substrate is 0.8*0.8 (i.e., 80%*80%). Thus, to create an exemplary broadband absorptive neutral density optical filter in accordance with this embodiment of the present invention having an optical transmission of 10%, 80 layers of graphene would be grown on the SiC substrate, i.e., 0.1≈(0.8*0.8)*(1−0.023)⁸⁰.

Another exemplary embodiment of a broadband absorptive neutral density optical filter in accordance with the present invention comprises graphene layers grown separately on a “donor” surface, e.g., by chemical vapor deposition on SiC, that have been removed from the donor surface and transferred to a substrate appropriate to the wavelengths of interest. For example, if the filter is to be used for attenuation/transmission of light in the visible range between 400 and 700 nm, one or more layers of graphene can be grown on an SiC substrate and then transferred to an appropriate optical substrate such a fused silica substrate. On the other hand, if the filter is to be used in THz radiation applications, where the spectrum of interest is in the 1 mm wavelength range, the graphene can be transferred to a substrate in the form of a wire mesh. Removal of the graphene from the growth surface and subsequent transfer to the optical substrate can be done by any appropriate method known in the art, such as the double-flip transfer method described in Caldwell et al., supra or the dry transfer method described in Lock et al., supra. In addition, as noted above, in some cases the graphene can be grown and transferred one layer at a time while in other cases multiple layers can be grown, with the multiple layers being transferred either in stages or all at once.

As in the previous embodiment, the number of graphene layers used may depend on the level of optical attenuation desired and the optical substrate used. In an exemplary case, to create a neutral density filter having an optical transmission of 50% on a wire mesh substrate, 30 graphene layers can be grown on the donor surface and then transferred to the substrate.

In a further embodiment, aspects of which are illustrated in FIG. 6, light attenuation is needed in an existing optical system having a removable optical element. In this embodiment, one or more layers of graphene 602 can be grown on a substrate 601 and removed from the growth substrate, for example, as described in Caldwell et al., supra, or Lock et al., supra, and then conformally deposited onto optical element 603 to provide the desired level of light attenuation. When the optical element is replaced, the optical system receives uniform absorption from the graphene layers.

Advantages and New Features

The present invention provides a number of advantages over currently available absorptive neutral density optical filters.

For example, an absorptive neutral density optical filter in accordance with the present invention exhibits a uniform response from the visible through the IR spectral region, as opposed to conventional filters which are often implemented by either dielectric coatings or vitrified absorptive elements. In either case it is difficult to find a material that produces a constant absorption as a function of wavelength. One way to improve these characteristics is to use complimentary elements; however, this is complicated and can add additional expense.

In addition, an absorptive neutral density optical filter in accordance with the present invention can provide simple and scalable variable attenuation by varying the number of layers of graphene used to form the filter.

An absorptive neutral density optical filter in accordance with the present invention also provides improved thermal performance as compared to conventional optical filters. The absorption of light in conventional neutral density filters produces heat in the filter medium. This medium (e.g. glass) is has a low thermal conductivity and therefore quickly heats up causing a number of thermal issues, such as thermal lensing, which distort the spatial, spectral and temporal qualities of the transmitted light. In contrast, graphene has a high thermal conductivity, and as a result, localized absorptive heating is mitigated as the graphene rapidly conducts the heat away from the absorbing region. Thus, an absorptive neutral density optical filter in accordance with the present invention can be used in applications having higher optical power than can be used with conventional absorptive neutral density filters.

In addition to thermally induced changes in optical transmission, irreversible optical damage can occur to the absorptive neutral density filters. Due to its material properties, the optical damage threshold of graphene exceeds those of conventional absorptive materials in neutral density filters, allowing graphene optical filters to operate into higher optical intensity regimes.

Moreover, such filters can be transferred to a variety of substrates or can be transferred into existing optical devices without degradation of these optical and thermal advantages.

These advantages enable optical filters in accordance with the present invention to be used with a wide variety of optical elements of varying sizes and thus to be used for a wide variety of applications such as extended time-exposure imaging; wide-aperture (low depth of field) imaging; increasing contrast in high-optical-brightness environments; protecting optical equipment from damage caused by excessive light; in optical systems where temporal and spectral attributes of optical signals are coupled; and in optical systems that require precise adjustment of the light intensity and that require preservation of all parameters of the input light (e.g. spatial, temporal, spectral, etc.). Other applications of the present invention can include safety equipment where light attenuation is desirable, such as welding hoods, safety glasses, and the like.

Such optical elements include lenses having a least one graphene layer disposed thereon to provide an optical system receiving uniform absorption of light from the at least one graphene layer, in which the optical transmission of the lens depending on the number of graphene layers disposed on the lens and an optical characteristic of the lens itself. In some such optical devices, the lens is a removable lens, where the at least one graphene layer has been grown on a growth substrate and transferred to the lens, with the graphene-layer coated lens then being replaced into the optical system.

The above describes and illustrates particular embodiments, aspects, and features in accordance with the present invention. However, one skilled in the art would readily appreciate that the invention described herein is not limited to only those embodiments, aspects, and features but also contemplates any and all modifications within the spirit and scope of the underlying invention described and claimed herein, and such combinations and embodiments are within the scope of the present disclosure.

1. A method for fabricating a broadband absorptive neutral density optical filter, comprising:
providing an optical substrate having an optical transmittance T_{S};
determining a desired degree of optical transmittance T_{F} of the filter; and
disposing n layers of graphene on the substrate;
wherein n is determined by the desired optical transmittance of the filter and the optical transmittance of the substrate in accordance with the relation T_{F}≈(T_{S}*T_{S})*(1−0.023)ⁿ.

2. The method for fabricating a broadband absorptive neutral density optical filter according to claim 1, wherein the optical substrate comprises at least one layer of a polymer, silicon carbide, sapphire, germanium or potassium bromide.

3. The method for fabricating a broadband absorptive neutral density optical filter according to claim 1, wherein the optical substrate comprises a wire mesh, the filter being configured for attenuation of THz radiation.

4. The method for fabricating a broadband absorptive neutral density optical filter according to claim 1, wherein the number of graphene layers n disposed on the optical substrate is configured to produce an optical transmission T_{F} of about 10%.

5. The method for fabricating a broadband absorptive neutral density optical filter according to claim 1, wherein the number of graphene layers n disposed on the optical substrate is configured to produce an optical transmission T_{F} of about 50%.

6. The method for fabricating a broadband absorptive neutral density optical filter according to claim 1, wherein at least one of the n graphene layers is epitaxially grown on the optical substrate.

7. The method for fabricating a broadband absorptive neutral density optical filter according to claim 1, wherein at least one of the n graphene layers is grown on a separate growth substrate and subsequently transferred to the optical substrate.

8. The method for fabricating a broadband absorptive neutral density optical filter according to claim 7, wherein the at least one separately grown graphene layer is grown on the growth substrate by chemical vapor deposition.

9. The method for fabricating a broadband absorptive neutral density optical filter according to claim 8, wherein the growth substrate comprises SiC and the optical substrate comprises fused silica.

10. A method for fabricating a broadband absorptive neutral density filtering optical system, comprising:
providing a lens having an initial optical transmittance T_{S};
determining a desired degree of optical transmittance T_{F} of the lens; and
disposing n layers of graphene on at least one surface of the lens;
wherein n is determined by the desired optical transmittance of the lens and the initial optical transmittance of the lens in accordance with the relation T_{F}≈(T_{S}*T_{S})*(1−0.023)ⁿ.

11. The method for fabricating a broadband absorptive neutral density filtering optical system according to claim 10, further comprising removing the lens from an existing optical system, transferring the n layers of graphene onto the at least one lens surface, and replacing the lens into the optical system.

12. The method for fabricating a broadband absorptive neutral density filtering optical system according to claim 10, wherein at least one of the n graphene layers is separately grown on a growth substrate and subsequently transferred to the at least one lens surface.

13. The method for fabricating a broadband absorptive neutral density filtering optical system according to claim 12, wherein the lens has at least one curved lens surface, and further wherein the graphene is transferred to the at least one curved lens surface.

14. The method for fabricating a broadband absorptive neutral density optical filter according to claim 1, wherein the substrate forms a three-dimensional structure, and wherein the graphene is disposed conformally over at least part of the three-dimensional structure.

15. The method for fabricating a broadband absorptive neutral density filtering optical system according to claim 12, wherein at least one of the transferred graphene layers is conformally deposited over the at least one surface.

16. The method for fabricating a broadband absorptive neutral density optical filter according to claim 1, wherein the substrate has at least one curved lens surface, and further wherein the graphene is transferred to the at least one curved lens surface.

17. The method for fabricating a broadband absorptive neutral density optical filter according to claim 8, wherein the at least one separately grown graphene layer is transferred to the substrate at a temperature below a temperature required for chemical vapor deposition.

18. The method for fabricating a broadband absorptive neutral density optical filter according to claim 8, wherein the at least one separately grown graphene layer is transferred to the substrate at a temperature of about 150° C.

19. The method for fabricating a broadband absorptive neutral density filtering optical system according to claim 12, wherein the at least one separately grown graphene layer is grown on the growth substrate by chemical vapor deposition.

20. The method for fabricating a broadband absorptive neutral density filtering optical system according to claim 19, wherein the at least one separately grown graphene layer is transferred to the substrate at a temperature below a temperature required for chemical vapor deposition.

21. The method for fabricating a broadband absorptive neutral density filtering optical system according to claim 19, wherein the at least one separately grown graphene layer is transferred to the substrate at a temperature of about 150° C.
